(19) United States
(12) Patent Application Publication
(10) Pub. No.: US 2025/0095959 A1
(43) Pub. Date: Mar. 20, 2025

(54) DELAYERING APPARATUS AND METHODS

(71) Applicant: FEI Company, Hillsboro, OR (US)

(72) Inventors: Chad Rue, North Plains, OR (US); Lilly Landers, Portland, OR (US); Jason Arjavac, Hillsboro, OR (US); Gavin Mitchson, Portland, OR (US)

(73) Assignee: FEI Company, Hillsboro, OR (US)

(21) Appl. No.: 18/369,967

(22) Filed: Sep. 19, 2023

(51) Int. Cl. H01J 37/305

(52) U.S. Cl. CPC H01J 37/3056; H01J 2237/006; H01J 2237/226; H01J 2237/31745

(57) ABSTRACT

Methods include conditioning at least a portion of a gas delivery system with a carbon-based conditioning agent to provide a carbon-based residual, and etching a substrate with a focused ion beam, in the presence of an ammonia-based delayering agent provided by the gas delivery system and in the presence of the carbon-based residual, wherein the carbon-based residual reduces a topographical variation of a depth of the etching. Apparatus include a focused ion beam system configured to deliver a focused ion beam to a sample, and a pre-conditioned gas delivery system configured to deliver an ammonia-based delayering agent to the sample at least while the focused ion beam is being delivered to the sample, wherein the pre-conditioned gas delivery system includes a carbon-based residual in the gas delivery system, wherein a portion of the carbon-based residual is present at the sample during the etching of the sample with the ammonia-based delayering agent.

### FIELD

The field is charged particle beam processing of targets and samples, more particularly delayering of targets and samples.

### BACKGROUND

In the pursuit of smaller and more intricate microelectronic devices, it becomes increasingly difficult to analyze or confirm the characteristics of the structures that are made. Some analyses can involve finely processing an area of a sample with a focused ion beam to carefully remove one or more layers of material. However, existing approaches can fail to reliably provide useful information about structures of interest. Therefore, a need remains for improved apparatus and methods to process related materials.

### SUMMARY

According to an aspect of the disclosed technology, methods include conditioning at least a portion of a gas delivery system with a carbon-based conditioning agent to provide a carbon-based residual, and etching a substrate with a focused ion beam, in the presence of an ammonia-based delayering agent provided by the gas delivery system and in the presence of the carbon-based residual, wherein the carbon-based residual reduces a topographical variation of a depth of the etching. In some examples, the carbon-based conditioning agent comprises a hydrocarbon. In some examples, the carbon-based conditioning agent comprises a benzene ring. In some examples, the carbon-based conditioning agent comprises naphthalene and/or phenanthrene. In some examples, the carbon-based conditioning agent comprises a carbon-based deposition precursor. In some examples, the carbon-based conditioning agent consists essentially of benzene, naphthalene, phenanthrene, biphenyl, toluene, xylene, styrene, ethylbenzene, trimethylbenzene, tetramethylbenzene, pentamethylbenzene, hexamethylbenzene, n-propylbenzene, and/or cumene. In some examples, the ammonia-based delayering agent comprises ammonium carbonate. In some examples, the ammonia-based delayering agent comprises ammonium bicarbonate. In some examples, the ammonia-based delayering agent comprises anhydrous ammonia, either by itself or mixed with water and carbon dioxide. Some examples include, after the etching, imaging the substrate with a charged particle microscope. Some examples include forming a 3D image of the substrate from a plurality of image slices of the substrate.

According to another aspect of the disclosed technology, apparatus include a focused ion beam system configured to deliver a focused ion beam to a sample, and a pre-conditioned gas delivery system configured to deliver an ammonia-based delayering agent to the sample at least while the focused ion beam is being delivered to the sample, wherein the pre-conditioned gas delivery system includes a carbon-based residual in the gas delivery system, wherein a portion of the carbon-based residual is present at the sample during the etching of the sample with the ammonia-based delayering agent. In some examples, the gas delivery system is configured to provide a carbon-based conditioning agent to at least a portion of the gas delivery system to leave the carbon-based residual in the gas delivery system, wherein the carbon-based residual reduces a depth variation in the etching of the sample by the focused ion beam. In some examples, the carbon-based conditioning agent comprises a hydrocarbon. In some examples, the carbon-based conditioning agent comprises a benzene ring. In some examples, the carbon-based conditioning agent comprises naphthalene. In some examples, the carbon-based conditioning agent consists essentially of benzene, naphthalene, biphenyl, phenanthrene, toluene, xylene, styrene, ethylbenzene, trimethylbenzene, tetramethylbenzene, pentamethylbenzene, hexamethylbenzene, n-propylbenzene, and/or cumene. In some examples, the ammonia-based delayering agent comprises ammonium carbonate, ammonium bicarbonate, and/or anhydrous ammonia, used either by itself or in combination with water and carbon dioxide. Some examples include a charged particle microscope imaging system configured to image the substrate after the etching, and wherein the imaging system is configured to form a 3D image of the substrate from a plurality of image slices of the etched substrate.

According to another aspect of the disclosed technology, apparatus include a computer processor and computer memory, wherein the memory includes code that, when executed by the processor, causes the processor to cause a focused ion beam system to condition at least a portion of a gas delivery system of the focused ion beam system with a carbon-based conditioning agent to provide a carbon-based residual, and etch a substrate with a focused ion beam, in the presence of an ammonia-based delayering agent provided by the gas delivery system and in the presence of the carbon-based residual.

The foregoing and other objects, features, and advantages of the disclosed technology will become more apparent from the following detailed description, which proceeds with reference to the accompanying figures.

### BRIEF DESCRIPTION OF THE DRAWINGS

FIG. 1 is a flowchart of example methods of line conditioning a gas delivery system and etching a substrate.

FIG. 2 is a flowchart of example methods of adjusting line conditioning and/or etching parameters.

FIG. 3 is a schematic of example focused ion beam etching apparatus.

FIG. 4 is a schematic of an example dual-beam system.

FIG. 5 is a perspective schematic of a read/write head for a hard disk storage device.

FIGS. 6A-6B are a top view and cross-sectional image traces, respectively, of a data storage sample of a read/write head.

FIGS. 7A-7B are perspective views of 3-D image reconstructions of delayered samples.

FIG. 8 is a perspective image of a delayered portion of a sample.

FIG. 9 is a cross-section image trace of another data storage sample.

FIGS. 10A-10D are cross-sectional image traces of similar data storage samples after different delayering attempts.

FIG. 11 is a graph of vertical etch rate with respect to experimental run.

FIGS. 12A-12B are cross-sectional image traces of similar data storage samples with no carbon-based line conditioning agents being used (FIG. 12A) and with a residual present (FIG. 12B).

FIGS. 13A-13D are cross-sectional image traces of similar data storage samples after delayering using a co-flowed carbon-based conditioning agent, at four different timestamps.

### DETAILED DESCRIPTION

### Introduction

Small microelectronic devices with structures of interest can include various data storage samples of increasingly smaller hard drive disk read and write heads. Such data storage samples can consist of materials that are different from traditional semiconductor logic or memory devices. For example, some data storage samples can consist primarily of a Ni/Fe alloy, Al₂O₃, and Ru, often arranged in detailed micron to nanometer scale three-dimensional configurations. Data storage researchers often wish to perform planar delayering (also referred to as etching herein) of the data storage samples, similar to an analogous application for logic and memory samples. However, device delayering of logic and memory samples typically utilizes gas-assisted FIB milling approaches, such as the Thermo Fisher Dx chemistry, that may not provide the same planarizing benefits for data storage samples.

Ammonium carbonate is one chemical precursor that shows some promise for delayering data storage samples. The chemical decomposes to produce a mixture of ammonia, water, and carbon dioxide. The ratio of gases changes somewhat as the precursor ages in the crucible. Also, the amount of purging and prior use of other gases can have a big impact on delayering performance. For this reason, ammonium carbonate has shown inconsistencies which has prevented it from being reliably used in delayering data storage samples.

As discussed further below, examples of the disclosed technology use a carbon-based precursor such as naphthalene in association with an ammonia-based delayering agent like ammonium carbonate to dramatically improve performance and consistency during delayering. Herein, ammonia-based agents can include chemicals that include, provide, or produce ammonia. For example, ammonium carbonate is an ammonia-based agent while it does not include ammonia directly but instead decomposes into ammonia, carbon dioxide, and water. An ammonia-based agent can refer to the chemicals that include, provide, or produce ammonia (and which might not include ammonia), and/or decomposition products such as ammonia that are flowed in the presence of a delayering target. For example, an agent can refer to both a source chemical that might not include ammonia (such as ammonium carbonate) and/or decomposition byproducts that include ammonia but do not include the source chemical. The carbon-based precursor can operate as a line conditioning agent for the gas delivery system (such as a multi-gas injection system, or MGIS) that provides the ammonia-based delayering agent. In many examples, the carbon-based line conditioning agent is flowed prior to the flowing of the ammonia-based delayering agent during or in association with the delayering process with a focused ion beam. In some examples, the carbon-based line conditioning agent is flowed during the flowing of the ammonia-based delayering agent. In some examples, the carbon-based line conditioning agent is flowed through an entire pathway of the gas delivery system used to deliver the ammonia-based delayering agent. In further examples, the carbon-based line conditioning agent is flowed through only a portion or sub-section of the gas delivery system, such as only being flowed into an enclosure of the gas delivery system or a sub-section of a flow pathway.

While not fully understood, and without limiting the scope of disclosed apparatus and method, it is thought that the mechanism for enhancement of the delayering process with ammonium relates to adsorption of the carbon-based line conditioning agent on structural surfaces of the gas delivery system, such as surfaces of the injection needle walls to form a carbon-based residual, e.g., in the form of a coating. The presence of the residual can affect the ratio of the water and ammonia vapors coming from the ammonia-based delayering agent. Without the carbon residual, the ratio may be less than optimal and the delayering results are generally poor and inconsistent.

Two primary hypotheses for how naphthalene helps include:
1. Residual naphthalene on the inside walls of the flow pathway modifies the composition of the effluent from the ammonium carbonate crucible in ways which are beneficial to subsequent delayering processes. Studies with Residual Gas Analyzer (RGA) instruments confirm that the ratios of water, ammonia, and carbon dioxide are somewhat different before and after exposing the delivery lines to naphthalene.
2. Residual naphthalene in the delivery lines reaches the sample and results in a thin layer of carbon deposition on the sample surface. If the deposition occurs selectively on features which would otherwise mill more quickly than surrounding materials, then this selective carbon deposition can have a protective nature which helps maintain planarity during the milling process.
   Both mechanisms seem plausible and experimental studies to date are unable to unambiguously distinguish the true mechanism. The preponderance of data suggests that the second mechanism is more likely.

### Example Methods

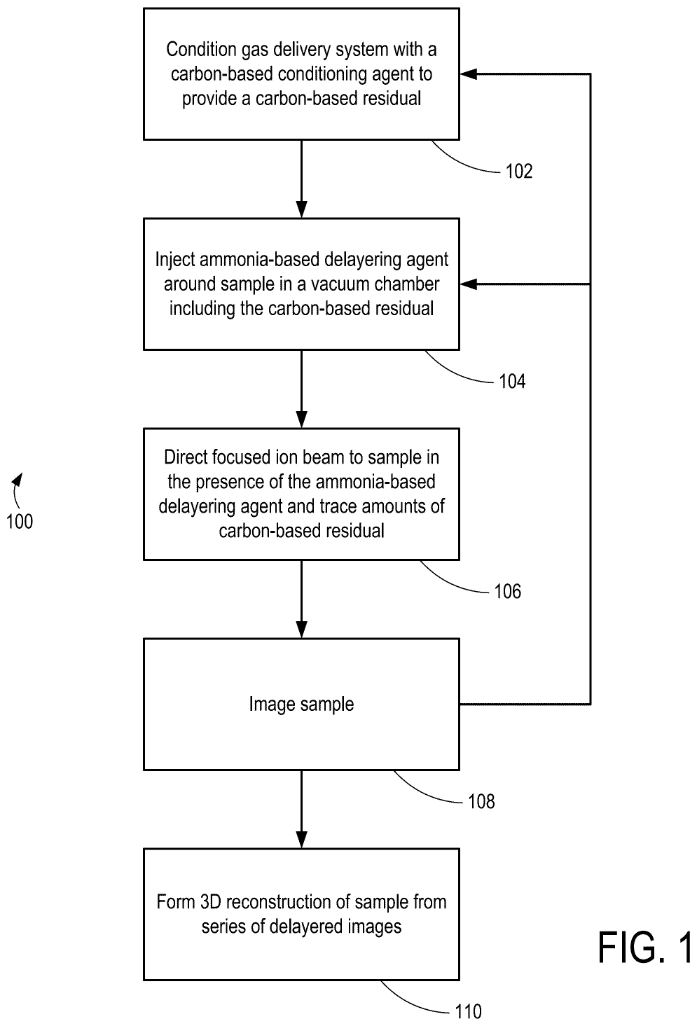

FIG. 1 shows example methods 100 of delayering a sample that can be arranged in a chamber of a vacuum environment. Example internal pressures in the chamber can controlled to be below about 1×10⁻³ torr, e.g., below 1×10⁻⁴ torr, 1×10⁻⁵ torr, 1×10⁻⁶ torr, etc. The chamber can be a part of a focused ion beam (FIB) system, or in some cases a dual-beam system that further contains an imaging column, such as a scanning electron microscope (SEM) column. The sample can be a data storage sample or other microelectronics sample to be delayered. Methods 100 can include, at 102, conditioning a line of a gas delivery system that couples one or more gases to the chamber. The line conditioning can include flowing a carbon-based conditioning agent through the gas delivery system to provide a carbon-based residual in the system. In representative examples, the carbon-based conditioning agent is predominantly the hydrocarbon naphthalene. In further examples, other hydrocarbons or other carbon-based agents or mixtures can be used, such as benzene, naphthalene, phenanthrene, and/or a compound having a benzene ring. Example carbon-based conditioning agents can also include toluene, xylene, styrene, ethylbenzene, trimethylbenzene (e.g., any of its three isomers), tetramethylbenzene (e.g., any of its three isomers), pentamethylbenzene, hexamethylbenzene, n-propylbenzene, and/or cumene. In many examples, the carbon-based conditioning agent consists essentially of one or more of the aforementioned hydrocarbons. In some examples, the carbon-based conditioning agent can be a chemical that may be used as a carbon deposition precursor, including, by way of example, chemicals that may be used to deposit carbon in an ion beam process. Many carbon-based conditioning agents can be hydrocarbons but carbon-based agents can include non-hydrocarbons as well. Some carbon-based deposition precursors can include acrylic acid, acetonitrile, etc.

The residual can reside on interior surfaces of the gas delivery system, such as needle or gas line walls, or other surfaces, such as exterior surfaces of the gas delivery system, vacuum chamber walls, etc., and can reside in a gas state, e.g., adjacent to residual coating, throughout gas delivery lines, and/or within the vacuum chamber. In many examples, a separate crucible or other container holds the carbon-based line conditioning agent and it is allowed to flow through the needle, chamber, and/or other portions of the gas delivery system through controlled release, typically for a preselected duration (e.g., 5 second, 30 seconds, 5 minutes, etc.).

At 104, an ammonia-based delayering agent is injected through the gas delivery system, e.g., with a gas injection needle of the gas delivery system, to provide the ammonia-based delayering agent gas in proximity to the sample to be delayered. The ammonia-based delayering agent typically provides ammonia (NH₃) in some form or mixture. For example, the ammonia-based delayering agent can include ammonium carbonate, ammonium bicarbonate, and/or a controlled mixture of ammonia and water. In some examples, the ammonia-based delayering agent can initially consist essentially of ammonium carbonate, ammonium bicarbonate, and/or a mixture of the two. In some examples, ammonia can be delivered directly, e.g., in anhydrous form, and/or mixed with various quantities of other gases such as water and carbon dioxide. Residue from the line conditioning step with a carbon-based precursor such as naphthalene can mix with the delayering agent so that the carbon-based residual is also present in small amounts with the delayering agent in proximity to the sample to be delayered. In some examples, the line conditioning at 102 can be performed concurrently with the injection of the ammonia-based delayering agent. In more typical examples, the line conditioning at 102 is performed prior to the flowing of the ammonia-based delayering agent, or flowing of the line conditioning agent terminates before the flowing of the ammonia-based delayering agent or other delayering process steps are completed.

In the presence of the delayering agent and the carbon-based residual, at 106, a focused ion beam (FIB) is directed to the sample. The focused ion beam is typically scanned quickly across a target area of the sample (e.g., 1 μm², 10 μm², 100 μm², etc.) for a process duration (e.g., 1 s, 10 s, 100 s, etc.). The focused ion beam is typically scanned multiple times across the area. The process duration can be associated with removal of material to an average depth, e.g., 1 nm, 5 nm, 10 nm, 50 nm, etc. The depth is typically measured perpendicular to a planar surface of the sample. The presence of the carbon-based residual during the processing with the focused ion beam can allow for reduced depth variation in the removed material. E.g., regions of the target area that can be observed to have notched topographical features associated with removal of excess material and/or ridged topographical features associated with a failure to remove material, can be observed to have smaller notched and/or ridged topographical variation after performing similar processing in the presence of the carbon-based residual. For example, processing with an ammonia-based delayering agent without the presence of the carbon-based residual can be associated with a depth variation after delayering of ±10%, ±20%, ±40%, ±60%, or ±100%, and inconsistency in depth variation between delayering steps or sample processing sessions of 20%, 50%, 100%, 200%, or more. In contrast, processing with an ammonia-based delayering agent along with the presence of the carbon-based residual can be associated with a reduced depth variation after delayering of ±0.5%, ±1%, ±2%, ±5%, ±10%, or ±20%, and an increased consistency in depth variation between delayering steps or sample processing sessions of less than or equal to 1%, 5%, 10%, or 20%.

In many examples, methods 100 can be used to collect image data of the different layers of the sample to collect layered information, e.g., to form a three-dimensional reconstruction of the sample. In some instances, only a single delayering step can be performed. After the focused ion beam is directed to the sample and material is removed to a depth, at 108, an image of the sample can be collected. In some examples, the sample can be transferred to a separate imaging system, such as a separate scanning electron microscope. In representative examples, the imaging can be performed in the same system having a dual beam configuration. For example, in some of such system examples, the sample can be rotated to face a charged particle beam from an imaging column. In many examples, after image collection at 108, the process of delayering another layer can be repeated at 102, 104, 106. In some examples, the line conditioning providing the carbon-based residual at 102 need not be performed prior to or during each set of injecting the delayering agent at 104 and milling the sample at 106, as the remaining residual provided at 102 may be sufficient for multiple delayering steps on the target area, for delayering steps applied to new regions of the target, or for delayering steps applied to additional separate samples. In some examples, after multiple layers of the sample are removed and each new surface is imaged, a three-dimensional reconstruction of the sample can be produced using known image reconstruction or image stacking techniques. The reduced depth variation in each layer causes each layer to have a more planar profile, thereby allowing for a more accurate three-dimensional image reconstruction.

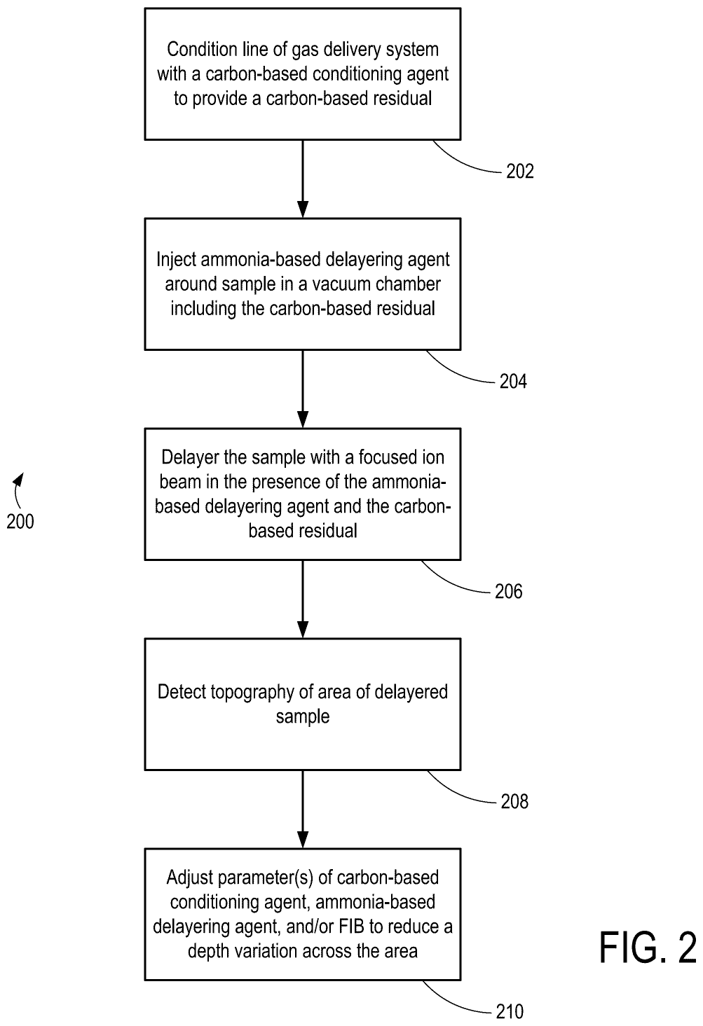

FIG. 2 are example methods 200 for controlling depth variation in the delayering of a sample. At 202, a gas delivery system can be line conditioned with a carbon-based conditioning agent. The line conditioning provides a carbon-based residual that can be situated as a coating of one or more surfaces of the gas delivery system and as an associated gas that can persist and mix with subsequent injections of a delayering agent. After or concurrently, at 204, an ammonia-based delayering agent gas can be injected to be within proximity of a sample in a vacuum chamber using the gas delivery system. Some of the carbon-based residual can be present in the injected ammonia-based delayering agent and at 206 the sample can be delayered with a focused ion beam in the presence of the delayering agent and carbon-based residual. The presence of the carbon-based residual can reduce a depth variation in the delayered portion of the sample relative to the depth variation in the delayered portion of the sample without the presence of the carbon-based residual, e.g., delayering the sample with only the ammonia-based delayering agent. At 208, a topography of the delayered sample can be detected to analyze the depth variation of a delayered area. The topography can be detected with various techniques, e.g., imaging with an electronic microscope, ellipsometry, CD-SEM, OCD, etc. At 210, one or more parameters associated with the line conditioning, ammonia-based delayering agent, and/or focused ion beam can be adjusted to further reduce a depth variation of a delayering. Example parameters can include the type or concentration of carbon-based line conditioning agent and/or ammonia-based delayering agent, duration of line conditioning, delay or overlap between delivery of carbon-based line conditioning agent and/or ammonia-based delayering agent, and FIB characteristics including ion energy (e.g., between about 2 keV and about 12 keV), spot size, and/or scan rate.

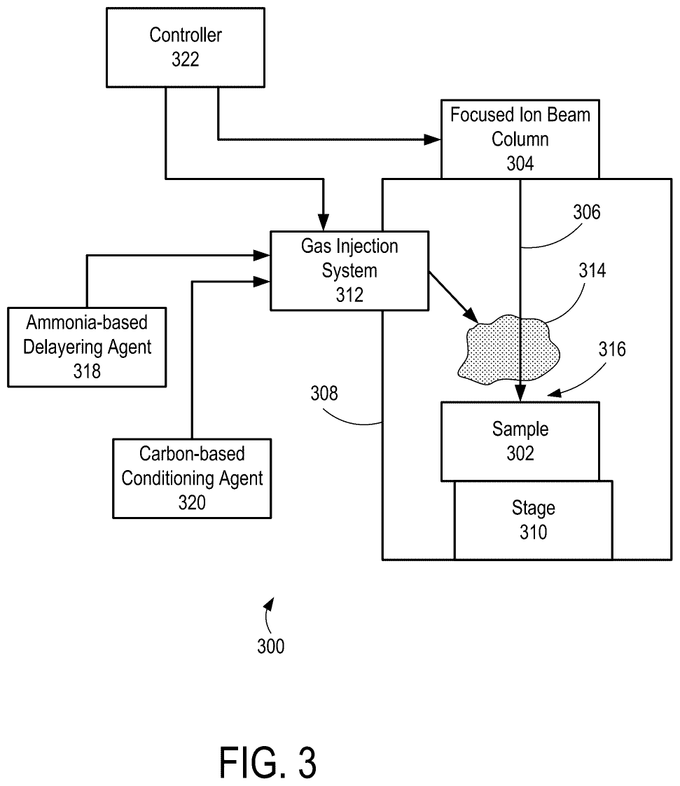

Example apparatus and systems FIG. 3 is an example system 300 that can be used to delayer a microelectronics sample 302, such as a data storage sample. The system 300 includes a focused ion beam column 304 configured to produce and direct a focused ion beam (FIB) 306 to the sample 302 situated in a vacuum chamber 308. Example internal pressures of the vacuum chamber 308 can be below about 1×10⁻³ torr, e.g., below 1×10⁻⁴ torr, 1×10⁻⁵ torr, 1×10⁻⁶ torr, etc., and can be provided by a vacuum pump. The sample 302 is typically arranged on a stage 310 which may be used to control a relative positioning of the sample 302 and the ion beam 306 or other beams (such as an imaging beam). The system 300 further includes a gas injection system 312 configured to release one or more gases 314 into a region 316 proximate the sample 302. The one or more gases can include an ammonia-based delayering agent 318. The gas injection system 312 can also be configured to release a carbon-based conditioning agent 320. The carbon-based conditioning agent can be released into one or more delivery lines of the gas injection system 312, such as a line or needle delivering the ammonia-based delayering agent and/or within the vacuum chamber 308, such as to the region 316. The carbon-based conditioning agent 320 can be released before or concurrently with release of the ammonia-based delayering agent. In some examples, the ammonia-based delayering agent 318 and/or carbon-based conditioning agent 320 can be arranged in storage crucibles inside the vacuum chamber 308.

The system 300 can further include a system controller 322 configured to control operation of various components of the system 300, such as timing and release of the ammonia-based delayering agent 318 and carbon-based conditioning agent 320, movement of the stage 310, vacuum pressure of the vacuum chamber 308, temperature, delivery of the focused ion beam 306, etc. Various chemicals can be used for the ammonia-based delayering agent 318 and carbon-based conditioning agent 320, as discussed elsewhere herein. By using the carbon-based conditioning agent, a reduced depth variation can be obtained after forming planar surfaces through delayering selected samples, such as data storage samples, samples containing Ni/Fe alloy, Al₂O₃, and/or Ru, or other samples.

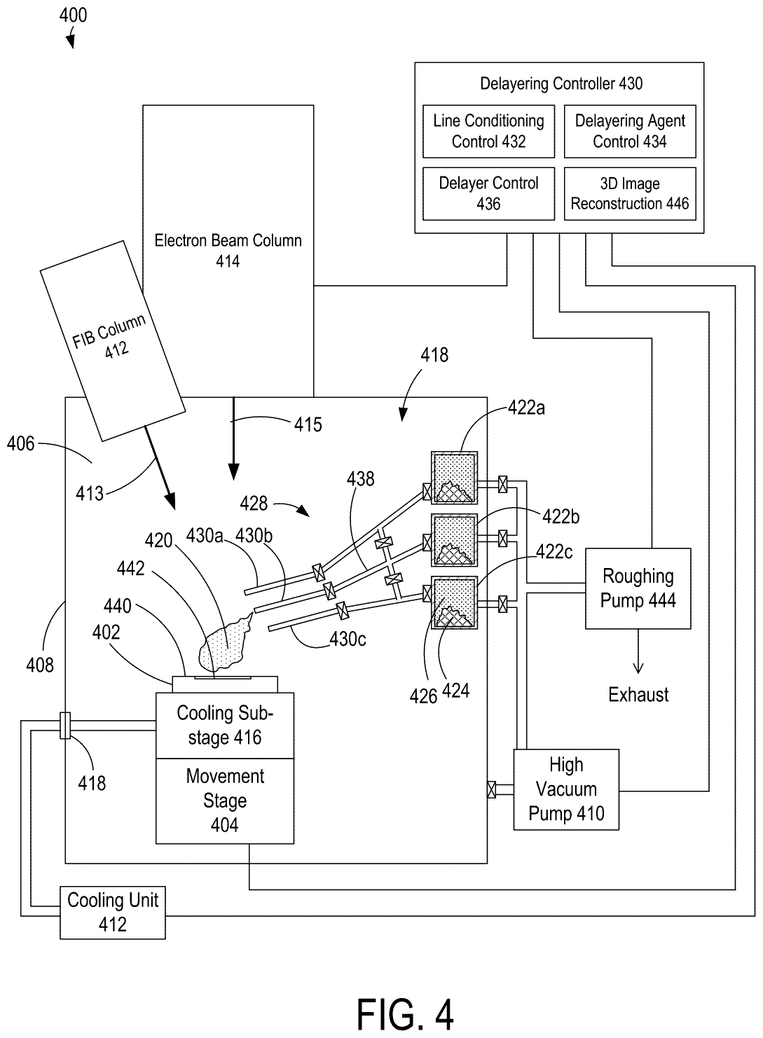

FIG. 4 is an example dual-beam system 400 configured to delayer a sample 402. The sample 402 can be arranged on a support structure, such as a movement stage 404, within an interior volume 406 of a vacuum chamber 408. A vacuum pump 410 can be coupled to the vacuum chamber 408 to reduce the internal pressure of the volume 406. Example internal pressures can be below about 1×10⁻³ torr, e.g., below 1×10⁻⁴ torr, 1×10⁻⁵ torr, 1×10⁻⁶ torr, etc. In many examples, when not flowing precursor substances, chamber pressures are usually in the range 5×10⁻⁷ to 5×10⁻⁶ mbar. When flowing precursor substances such as delayering agents, line conditioning agents, protective cap precursors, and/or other chemistries, into the chamber 408 proximate the sample 402, the chamber pressure can increase, e.g., from 5×10⁻⁶ up to 5×10⁻⁵ mbar.

The system 400 includes a focused ion beam (FIB) column 412 configured to direct a focused ion beam 413 to the sample 402 to remove material from the sample 402. The focused ion beam 413 is typically scanned across the sample to remove the material, and material removal can be referred to as delayering, sputtering, or milling. Suitable ion species can include gallium, xenon, argon, nitrogen, oxygen, etc. The system 400 also includes an electron beam column 414 configured to direct an electron beam 415 to the sample 402 to form an image of the sample 402. One or more detectors (not shown) are typically arranged in relation to the sample 402 to detect scattered, backscattered, and/or secondary electrons. In representative examples, the electron beam column 414 is a scanning electron microscope column configured to scan the electron beam in relation to the sample to create the image.

The movement stage 408 can be used to adjust positioning of the sample 402 relative to incident beam axes of the focused ion beam 413 and electron beam 415. In some examples, a cooling sub-stage 416 can be coupled to the movement stage 404 to control a temperature of the sample 402. For example, an external cooling unit 412 can be coupled to the vacuum chamber 408 via feedthrough 418 to pump a temperature control fluid to the cooling sub-stage 416.

The system 400 further includes a gas delivery system 418 coupled to the vacuum chamber 408 to controllably deliver one or more gases 420 proximate the sample 402. The gas delivery system 418, which can also be referred to as a gas injection system (GIS) or multi-gas injection system (MGIS), includes a plurality of containers 422a, 422b, 422c (shown in cross-section) situated in relation to the vacuum chamber 408 (e.g., inside, outside, etc.) and configured to store respective supplies of chemicals in a solid or liquid state 424 and/or gas state 426. Stored chemicals can include carbon-based line conditioning agents (such as naphthalene, benzene, etc.), ammonia-based delayering agents (such as ammonium carbonate, ammonium bicarbonate, etc.), protective cap precursors (such as carbon, platinum, or tungsten deposition precursors, etc.), as well as other chemicals suitable for sample processing with a FIB or dual-beam system, including chemical deposition. As shown, the containers 422a-422c are arranged inside the chamber 408, but it will be appreciated that one or more of the containers 422a-422c can be located outside the vacuum chamber 408 (e.g., attached to the exterior of the vacuum chamber 408) or formed into a wall structure of the vacuum chamber 408.

The containers 422a-422c can be held at a fixed temperature, e.g., in the range of 10° C. to 80° C. In many examples, the temperature of the containers 422a-422c or stored chemistries can be set by the user and can be changed. The system 400 can be configured to monitor the temperature and provide adjustments, e.g., to heating elements, as needed to keep the temperature at the set point. The gas delivery system 418 can include a flow pathway network 428 that can couple the respective containers 422a-422c to respective delivery needles 430a-430c, e.g., with valves (each shown as boxed ‘x’ in FIG. 4). The flow pathway network 428 can also be configured to couple different portions of the flow pathway network internally, e.g., to allow bypass routing of a gas from a selected container 422a-422c through a common portion of the flow pathway network 428. For example, gas from different containers 422a-422c can be routed through different delivery needles 430a-430c. In some examples, a single delivery needle may be used, e.g., needle 430b, and the flow pathway network 428 can selectively allow routing of different gases through the common needle 430b. In some examples, common or bypass routing is not present. In some examples, the temperature control can include different temperature zones along a length of the flow pathway network 428.

At a selected time, a delayering controller 430 (which can be part of or separate from a larger control system of the system 400 controlling other dual-beam system functions) can be configured with a carbon-based line conditioning control 432, an ammonia-based delayering agent delivery control 434, and focused ion beam delayer control 436. The line conditioning control 432 can be configured to cause release of a carbon-based line conditioning agent, e.g., stored in container 422a. In some examples, the carbon-based line conditioning agent can be released into a portion of the flow pathway network that overlaps a delivery path of an ammonia-based delayering agent that is released subsequently or concurrently with release of the carbon-based line conditioning agent. For example, the ammonia-based delayering agent can be stored in container 422b, and the carbon-based line conditioning agent can be released from container 422a into network portion 438. In some examples, the carbon-based line conditioning agent is not released into the chamber 408. In some examples, the carbon-based line conditioning agent can be released into the chamber 408, e.g., proximate the sample 402, through a common needle used to release the ammonia-based delayering agent, e.g., needle 430b. In further examples, the carbon-based line conditioning agent can be released into the chamber 408 using a separate needle, e.g., needle 430a. In some instances, the carbon-based line conditioning agent can be released before the sample 402 is arranged in the chamber 408. Release of the carbon-based line conditioning agent can produce a gas and/or solid/liquid carbon-based residual, e.g., on or in the flow pathway network 428 (including but not limited to portion 438), delivery needles 430a-430c, and/or exposed surfaces of the chamber 408 (including but not limited to external surfaces of the gas delivery system 418). During a delayering process, the ammonia-based delayering agent is released proximate a surface 440 of the sample 402, and the focused ion beam 415 is directed to the surface 440 in the presence of the ammonia-based delayering agent that can include some of the carbon-based residual. The surface 440 is delayered to expose a new layer 442. The presence of the residual during the processing of the sample with the ammonia-based delayering agent and focused ion beam can reduce a depth variation in the new surface 442. In particular examples, the reduced depth variation is obtained in data storage samples containing various metals such as Ni/Fe alloy, Al₂O₃, and/or Ru.

In some examples of the system 400, the containers 422a-422c can be coupled to a vacuum pump 444, which can be the same or different than the pump 410. In representative examples, the pump 444 can be situated external to the chamber 408 and vacuum coupled to the containers 422a-422c. In some examples, the vacuum pressure applied to the containers 422a-422c via the pump 444 can be a rough vacuum pressure, e.g., about 1×10⁻³ torr or greater, 1×10⁻² torr or greater, 1×10⁻¹ torr, etc.

After delayering to expose the new surface 442, the electron beam column 414 can be used to collect images of the new surface 442. After a plurality of images of delayered surfaces is obtained, the controller 430 or another processor or processing unit can be configured with a 3D image reconstruction routine 446 that retrieves the collection of images from memory and stacks to form a 3D image of the sample 404.

### Experimental Results

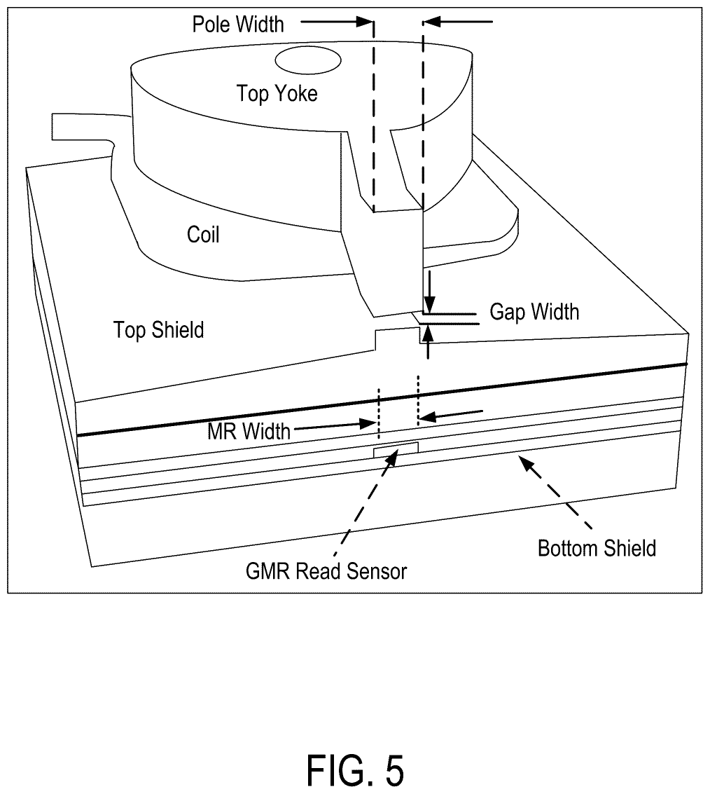

Disclosed apparatus and methods can be applied to a range of samples, particularly in the context of deconstruction, three-dimensional imaging, and related analyses to determine flaws or confirm correspondence with intended build parameters. As discussed above, the disclosed technology is particularly well-suited to data storage samples. FIG. 5 shows an example of a read/write head of a hard drive that uses giant magnetoresistance (GMR) to increase storage density. In practice, a data storage element (such as a disk) can be arranged to face and move relative to the read/write head that is shown. Data storage samples can correspond to portions of read/write heads of hard disk drives, such as the one depicted in FIG. 5. Microelectromechanical systems employing GMR can allow scaling of data storage into the tens of terabytes and higher. However, the read/write heads and various components of the systems are increasingly small and often employ various metals, including rare transition metals such as Ruthenium in proximity to other metals and non-metals.

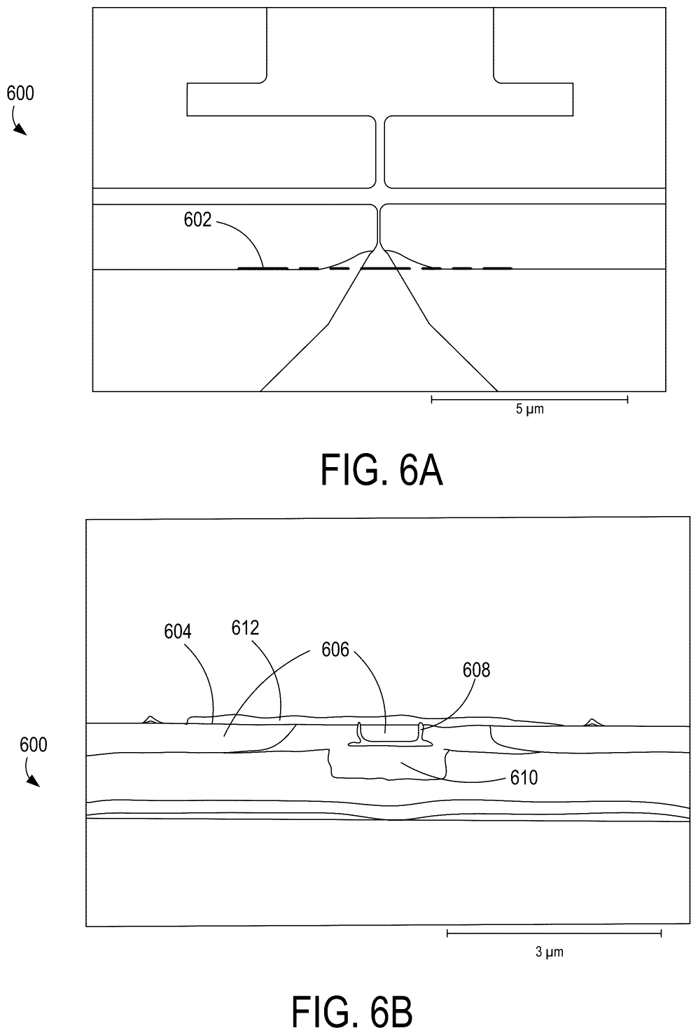

To prepare and analyze data storage samples, a process can involve imaging a surface with an SEM, removing a layer of material a few nm thick with a focused ion beam (FIB), and then re-imaging the new surface. The process can be repeated to remove multiple layers, so that as the surface gradually recedes in a z-direction a series of images can be obtained. In general, it is desirable that each new surface is smooth and flat rather than a topography with high spots and low spots. Such a depth variation can cause problems in the three-dimensional images forming reconstructions of the delayered data storage sample as well as other problems. However, such depth variations are difficult to address in practice due to the complexity of the physical geometry and material composition of the sample. FIG. 6A shows an SEM image trace of a top view of a data storage sample 600 and FIG. 6B shows a cross-sectional view of the same data storage sample 600 cut along cutting line 602. FIG. 6B reveals some features of interest, with a vertical direction corresponding to a delayering z-direction, i.e., perpendicular to layers that are formed and imaged. In this particular data storage sample, a delayered surface 604 reveals nickel/iron alloy regions 606 adjacent to a ruthenium region 608 and an aluminum oxide (Al₂O₃) region 610. A carbon protective cap 612 is also visible after being formed after delayering to form the surface 604, so as to provide fewer curtaining artifacts in the cross-sectioning of the sample 600. An unevenness in depth variation of the delayered surface 604 can occur near transitions between the regions 606, 608, 610.

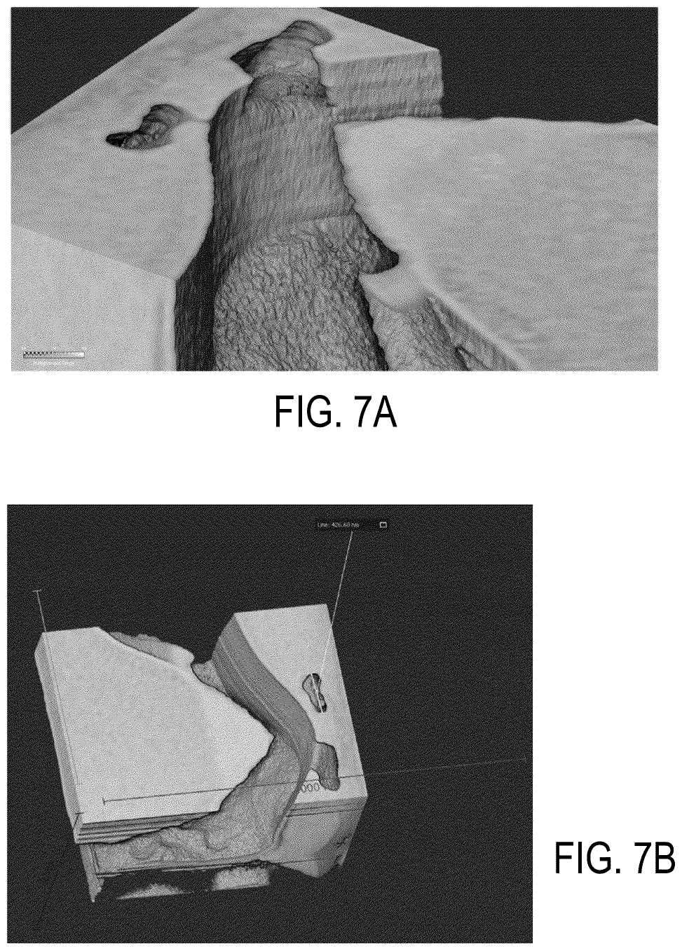

FIGS. 7A-7B are examples of 3D volumes that can be reconstructed using a series of 2D images obtained through a delayering process. The 3D reconstructions can be used to illustrate voids or defects in a layered structure.

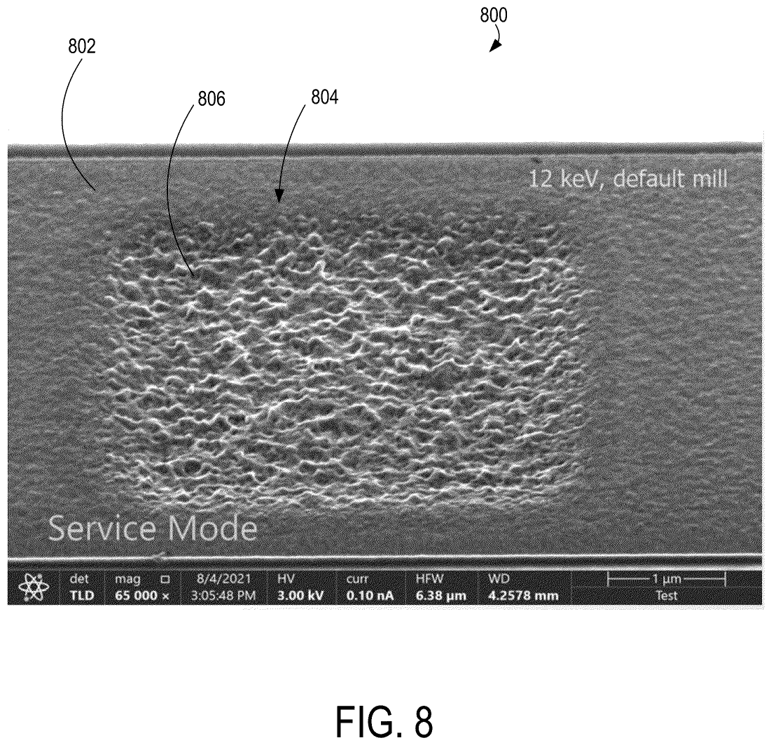

FIG. 8 shows a sample material 800 having a surface 802 that has been delayered with a focused ion beam across a square area region 804 to expose a new surface 806. The new surface 806 is formed having a significant topographical depth variation across the region 802, which can be undesirable in a delayering process. For example, in various instances milling with a FIB can quickly develop undesirable surface texture due to numerous factors. In the instance shown in FIG. 8, the surface texture arises from the polycrystalline characteristics of the underlying metal, as some crystalline grains mill faster and some mill more slowly thereby causing the development of high spots and low spots. Thus, in general, it can be difficult to maintain planarity in the delayering process.

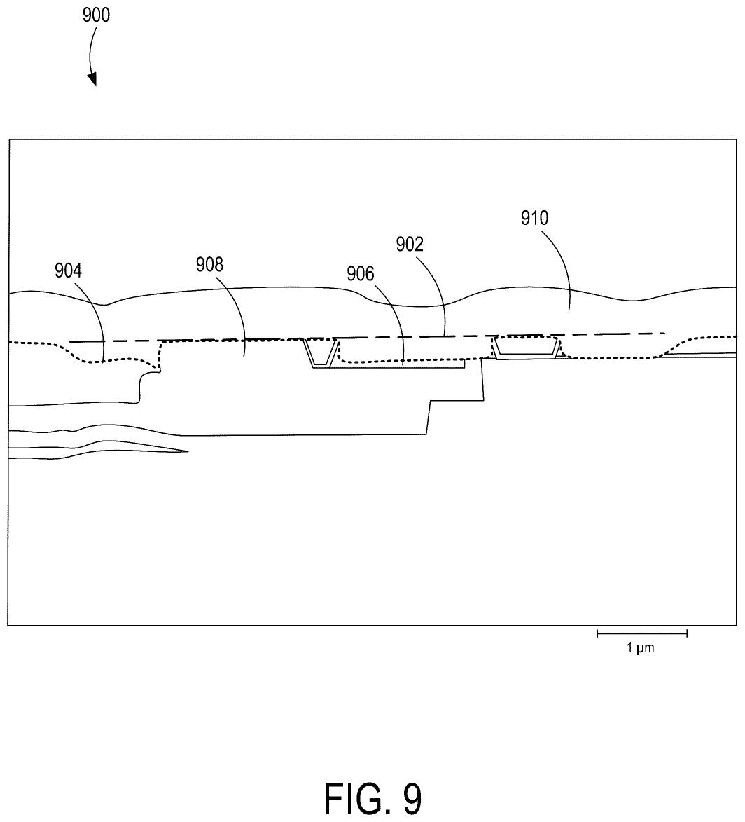

FIG. 9 is a delayered sample 900 in cross-section, similar to the cross-section shown in FIG. 6B. After a delayering process is performed down to a target plane 902, instead a surface 904 (dashed line) is formed which exhibits significant depth variation in the vertical direction, e.g., in the range of 10's to 100's of nm. Aluminum oxide regions 906 are adjacent to Nickel/Iron alloy regions 908. A protective Tungsten cap 910 is deposited after delayering to facilitate cross-sectioning. Thus, the aluminum oxide etches to a lower depth than a top surface of the metal alloy.

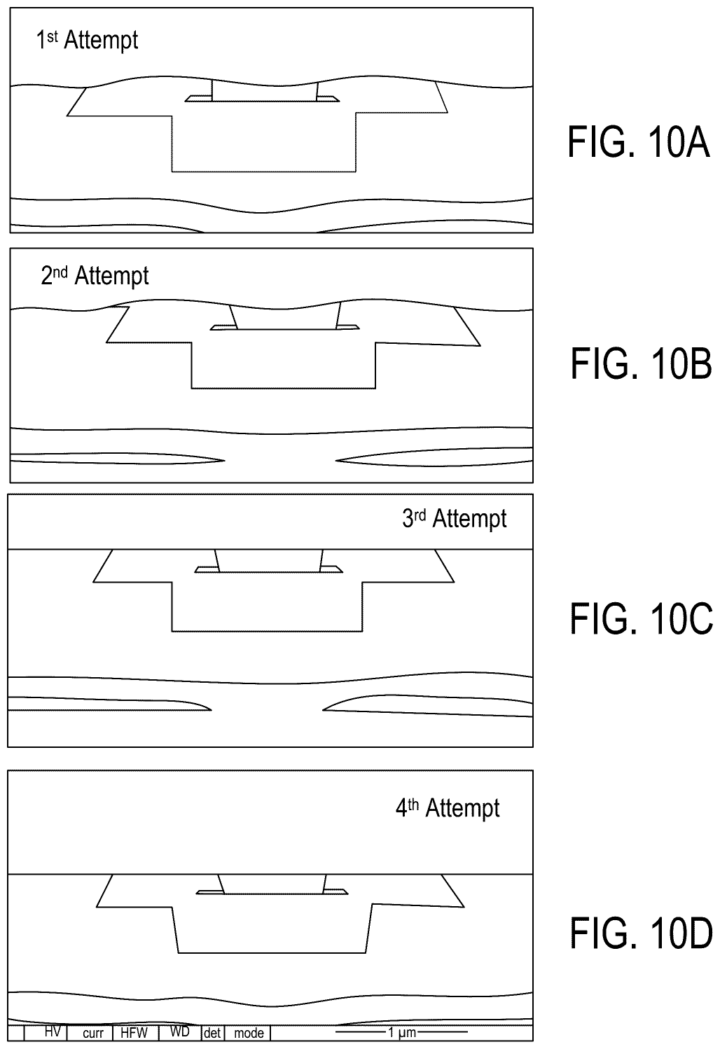

FIGS. 10A-10D show four experimental runs 1000A-1000D in which ammonium carbonate gas was flowed as a delayering agent at an area delayered with a focused ion beam. As can be seen from the cross-sections, a depth variation varies significantly across from run to run, with a significant amount of variation occurring in the runs 1000A, 1000B, some depth variation occurring in run 1000C, and very little planar variation occurring in the run 1000D. Disclosed examples using delayering agents and a carbon-based conditioning agent have been found to reduce the depth variation from run to run to provide more consistency and reduced depth variation in delayering processes.

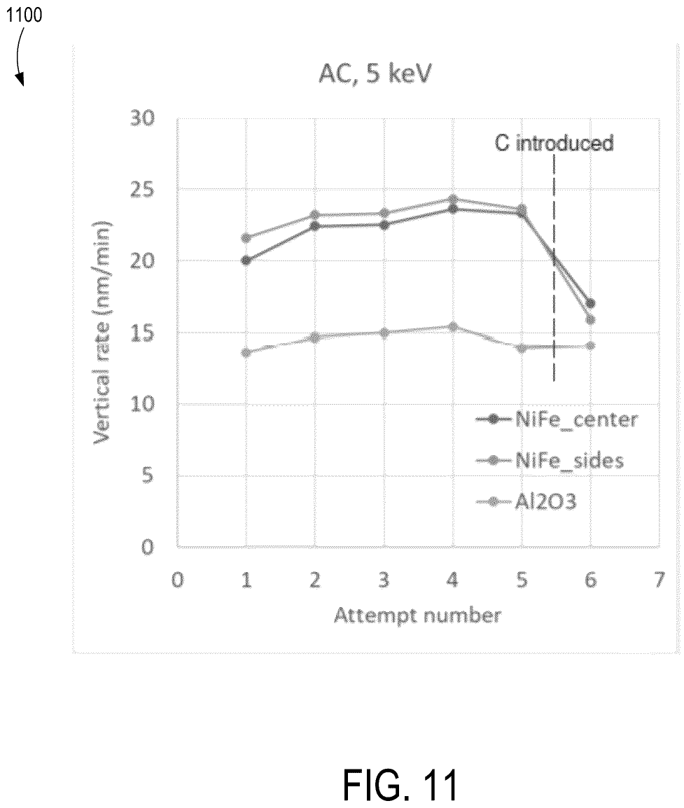

FIG. 11 is a graph 1100 comparing vertical rate of removal in nm/min of a similar structure of a data storage sample over six experimental runs. Depths were measured at common area locations corresponding to two different nickel/iron alloy regions and an aluminum oxide region. The delayering process used an ammonium carbonate delayering agent and exhibited depth variation between the aluminum oxide regions as compared to the nickel/iron alloy regions. However, after introduction of a carbon-based conditioning agent (here, naphthalene) at an interim step (e.g., to form a cap layer for a previous specimen), the subsequent delayering process with the ammonium carbonate was found to have the characteristically faster removal rate associated with the nickel/iron alloy regions become decreased. The decrease resulted in a positive convergence of etch rates between the aluminum oxide and alloy regions.

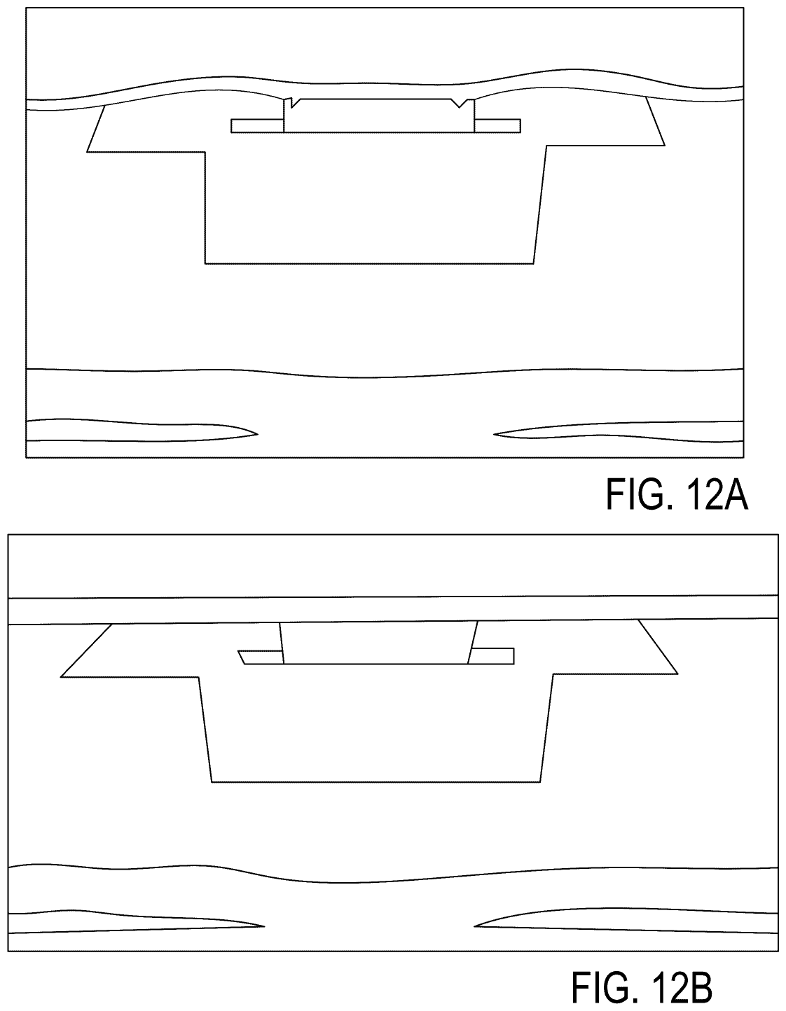

That is, during the normal delayering process, the gas delivery line delivers the ammonium carbonate delayering agent from its crucible to a gas delivery needle and then into the chamber and onto the sample. For the sixth run, that flow pathway was sensitive to the previous use of a carbon deposition precursor. By flowing the carbon deposition precursor (e.g., naphthalene) through the gas delivery lines for a few minutes and then subsequently performing the etching with ammonium carbonate, the depth variation is reduced. However, it is not found to be necessary that the carbon-based line conditioning agent be flowing during the delayering step with the focused ion beam and delayering agent gas. In some examples, the gas delivery line is conditioned with the carbon-based conditioning agent within 30 minutes of the etching. In further examples, other durations are possible, such as within 10 minutes, 45 minutes, 1 hour, etc. In this way, the amount of carbon residual in proximity to the sample during the delayering (e.g., mixed with the delayering agent gas) can be small relative to the delayering agent. The residual can be available for processing multiple areas, e.g., by persisting in the lines. For examples, percentage amounts of the carbon based residual relative to the delayering agent gas proximate the sample can be less than or equal to 1%, 0.1%, 0.01%, 0.001%, or less, of the delayering agent gas. FIGS. 12A-12B depict the depth variation difference, with FIG. 12A showing considerable depth variation and FIG. 12B showing very little depth variation.

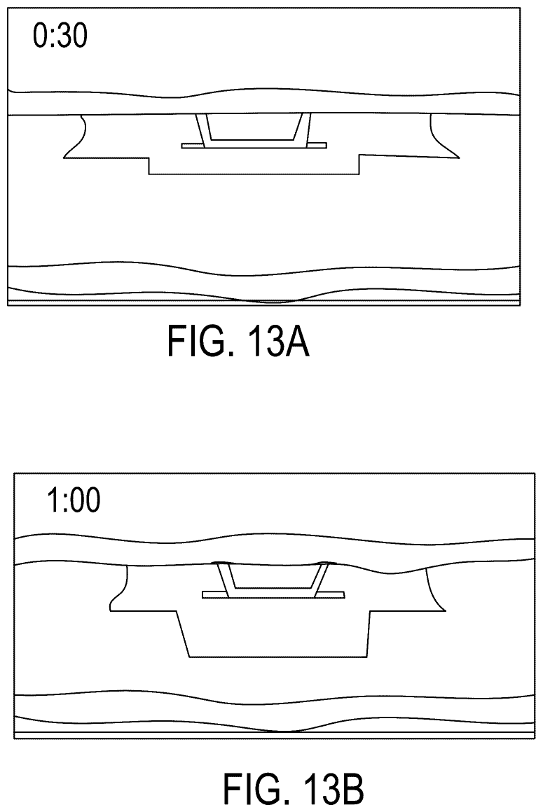

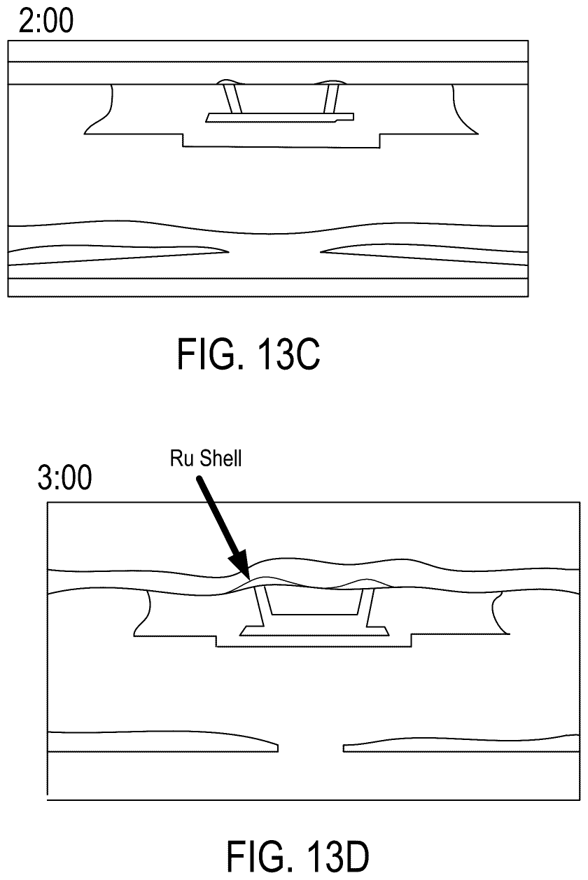

FIGS. 13A-13D show a time-evolution of carbon growth on a data storage sample surface for purposes of understanding underlying mechanisms facilitating reduced depth variation in etching of dissimilar materials. For example, carbon may be selectively accumulating on surfaces that would otherwise etch faster, thereby attenuating some of the etch rate for certain metals to provide positive convergence with etch rates of other materials (such as aluminum oxide). In this way, a selective deposition of carbon may be beneficially occurring. That is, a material that would etch very quickly because it is ‘soft’ to the focused ion beam, could receive a protective cap of carbon that can have a protective influence and slow down the etch rate of the material and increase planarity. One example of a soft spot that is observed in that a material location tends to be over-etched and notched, is proximate a ruthenium shell that surrounds a nickel/iron alloy region. This area has been found to be notched downwards after etching, and this notched topography can lead to additional non-planarities in other places. The time-evolution in FIGS. 13A-13D supports this hypothesis as carbon is seen to overlie the ruthenium shell. The carbon amounts used in the time-evolution study depicted in FIGS. 13A-13D are substantially higher than would be used to successfully reduce depth variation during a delayering process, but the time-evolution visually confirms selective accumulation. The time-evolution includes four different timestamps of the process in which we are coflowing a substantial amount of carbon with ammonium carbonate delayering agent. In the example shown, the carbon and ammonium carbonate were flowed 30 seconds, 1 minute, 2 minutes, and 3 minutes, for the respective timestamps, and the resulting sample was cross-sectioned.

In disclosed examples, various ammonia-based delayering agents may be used. As discussed previously, ammonium carbonate and ammonium bicarbonate are preferred examples of ammonia-based delayering agents. Ammonium carbonate decomposes naturally over time through a two-step decomposition process from ammonium carbonate into ammonium bicarbonate and ammonia, and then from ammonium bicarbonate into water, carbon dioxide, and another molecule of ammonia. Ammonium carbonate can be problematic as ammonium carbonate decomposes over time into ammonium bicarbonate, thereby having shelf-life characteristics that could affect performance. However, in many examples, ammonium carbonate can perform better than ammonium bicarbonate by allowing for a larger process window and behaving more reliably and robustly in various delayering processes.

### General Considerations

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatus' are referred to as “lowest”, “best”, “minimum,” or the like. It will be appreciated that such descriptions are intended to indicate that a selection among many used functional alternatives can be made, and such selections need not be better, smaller, or otherwise preferable to other selections.

The disclosed techniques may be, for example, embodied at least in part as software or firmware instructions carried out by a digital computer or controller. For instance, any of the disclosed delayering techniques can be performed by a computer or other computing hardware (e.g., an ASIC, FPGA, etc.) that is part of a focused ion beam system. The delayering system can be connected to or otherwise in communication with a gas delivery system and be programmed or configured to control gas delivery, timing for delivery of providing carbon-based line conditioning in relation to delayering agent gas delivery, delivery and scanning of a focused ion beam to delayer a sample, collection of images between delayering steps, movement of a sample on a sample stage, and/or reconstruction or formation of complex images. The computer or controller can be a computer system comprising one or more processors (processing devices) and tangible, non-transitory computer-readable media (e.g., one or more optical media discs, volatile memory devices (such as DRAM or SRAM), or nonvolatile memory or storage devices (such as hard drives, NVRAM, and solid state drives (e.g., Flash drives)). The one or more processors can execute computer-executable instructions stored on one or more of the tangible, non-transitory computer-readable media, and thereby perform any of the disclosed techniques. For instance, software for performing any of the disclosed embodiments can be stored on the one or more volatile, non-transitory computer-readable media as computer-executable instructions, which when executed by the one or more processors, cause the one or more processors to perform any of the disclosed delayering techniques. The results of the delayering and/or image results can be stored in the one or more tangible, non-transitory computer-readable storage media and/or can also be output to the user, for example, by displaying, on a display device, delayering performance parameters and/or images with a graphical user interface.

Having described and illustrated the principles of the disclosed technology with reference to the illustrated embodiments, it will be recognized that the illustrated embodiments can be modified in arrangement and detail without departing from such principles. For instance, elements of the illustrated embodiments shown in software may be implemented in hardware and vice-versa. Also, the technologies from any example can be combined with the technologies described in any one or more of the other examples. It will be appreciated that procedures and functions such as those described with reference to the illustrated examples can be implemented in a single hardware or software module, or separate modules can be provided. The particular arrangements above are provided for convenient illustration, and other arrangements can be used.

In view of the many possible embodiments to which the principles of the disclosed technology may be applied, it should be recognized that the illustrated embodiments are only representative examples and should not be taken as limiting the scope of the disclosure. Alternatives specifically addressed in these sections are merely exemplary and do not constitute all possible alternatives to the embodiments described herein. For instance, various components of systems described herein may be combined in function and use. We therefore claim all that comes within the scope of the appended claims.

We claim:

1. A method, comprising:
conditioning at least a portion of a gas delivery system with a carbon-based conditioning agent to provide a carbon-based residual; and
etching a substrate with a focused ion beam, in the presence of an ammonia-based delayering agent provided by the gas delivery system and in the presence of the carbon-based residual;
wherein the carbon-based residual reduces a topographical variation of a depth of the etching.

2. The method of claim 1, wherein the carbon-based conditioning agent comprises a hydrocarbon.

3. The method of claim 1, wherein the carbon-based conditioning agent comprises a benzene ring.

4. The method of claim 1, wherein the carbon-based conditioning agent comprises naphthalene and/or phenanthrene.

5. The method of claim 1, wherein the carbon-based conditioning agent comprises a carbon-based deposition precursor.

6. The method of claim 1, wherein the carbon-based conditioning agent consists essentially of benzene, naphthalene, phenanthrene, biphenyl, toluene, xylene, styrene, ethylbenzene, trimethylbenzene, tetramethylbenzene, pentamethylbenzene, hexamethylbenzene, n-propylbenzene, and/or cumene.

7. The method of claim 1, wherein the ammonia-based delayering agent comprises ammonium carbonate.

8. The method of claim 1, wherein the ammonia-based delayering agent comprises ammonium bicarbonate.

9. The method of claim 1, wherein the ammonia-based delayering agent comprises anhydrous ammonia, either by itself or mixed with water and carbon dioxide.

10. The method of claim 1, further comprising, after the etching, imaging the substrate with a charged particle microscope.

11. The method of claim 1, further comprising, forming a 3D image of the substrate from a plurality of image slices of the substrate.

12. An apparatus, comprising:
a focused ion beam system configured to deliver a focused ion beam to a sample; and
a pre-conditioned gas delivery system configured to deliver an ammonia-based delayering agent to the sample at least while the focused ion beam is being delivered to the sample;
wherein the pre-conditioned gas delivery system includes a carbon-based residual in the gas delivery system, wherein a portion of the carbon-based residual is present at the sample during the etching of the sample with the ammonia-based delayering agent.

13. The apparatus of claim 12, wherein the gas delivery system is configured to provide a carbon-based conditioning agent to at least a portion of the gas delivery system to leave the carbon-based residual in the gas delivery system, wherein the carbon-based residual reduces a depth variation in the etching of the sample by the focused ion beam.

14. The apparatus of claim 13, wherein the carbon-based conditioning agent comprises a hydrocarbon.

15. The apparatus of claim 13, wherein the carbon-based conditioning agent comprises a benzene ring.

16. The apparatus of claim 13, wherein the carbon-based conditioning agent comprises naphthalene.

17. The apparatus of claim 13, wherein the carbon-based conditioning agent consists essentially of benzene, naphthalene, biphenyl, phenanthrene, toluene, xylene, styrene, ethylbenzene, trimethylbenzene, tetramethylbenzene, pentamethylbenzene, hexamethylbenzene, n-propylbenzene, and/or cumene.

18. The apparatus of claim 12, wherein the ammonia-based delayering agent comprises ammonium carbonate, ammonium bicarbonate, and/or anhydrous ammonia, used either by itself or in combination with water and carbon dioxide.

19. The apparatus of claim 12, further comprising a charged particle microscope imaging system configured to image the substrate after the etching, and wherein the imaging system is configured to form a 3D image of the substrate from a plurality of image slices of the etched substrate.

20. An apparatus, comprising:
a computer processor and computer memory, wherein the memory includes code that, when executed by the processor, causes the processor to cause a focused ion beam system to:
condition at least a portion of a gas delivery system of the focused ion beam system with a carbon-based conditioning agent to provide a carbon-based residual; and
etch a substrate with a focused ion beam, in the presence of an ammonia-based delayering agent provided by the gas delivery system and in the presence of the carbon-based residual.
